(19) United States
(12) Patent Application Publication
(10) Pub. No.: US 2008/0030210 A1
(43) Pub. Date: Feb. 7, 2008

(54) Test socket

(75) Inventor: Wayne Hsieh, Tu-Cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/888,792

(22) Filed: Aug. 2, 2007

(30) Foreign Application Priority Data
Aug. 2, 2006 (CN) 200620075535.6

(51) Int. Cl. G01R 31/26; G01R 31/02

(52) U.S. Cl. 324/755; 324/765

(57) ABSTRACT

A test socket includes a socket body (20) having a passageway (42), and a terminal (30) insertable into the passageway. The passageway has a portion with an interior contour (421) in a predetermined plane along a length axis of said passageway. The terminal includes a resilient end (33) resiliently movable relative to the passageway. The resilient end has an exterior contour (331) in a common plane of the passageway, with the exterior contour in shape different from that of the interior contour of the passageway, such that during the movement of the resilient end, the exterior contour of the resilient end forms in point-to-point contact with the interior contour of the passageway. As compared with the prior art, the point-to-point contact between the terminal and the passageway can effectively reduce the abrasion of the terminal.

### BACKGROUND OF THE INVENTION

1. Field of the Invention

The present invention relates to the art of electrical connectors, and more particularly to a test socket.

2. The General Background

A conventional test socket typically includes a socket body defining a region for receiving an IC package to be tested, and a plurality of resilient terminals received within the socket body. The socket body further includes a bottom plate attached thereto, with a plurality of passageways defined in the bottom plate for receiving the resilient terminals. Each of the terminals includes a main body, upper and lower resilient ends on opposite sides of the main body. The lower resilient end of the terminal is resiliently movable with respect to the main body after compressed such that the lower resilient end movably extends into the passageway of the bottom plate. Since the lower resilient end has a rounded surface for engagement with a substantial rounded surface of the passageway, the lower resilient end will form a surface-frictional movement with respect to the passageway, and in some instance, even form an interference with the passageway. This will result in the abrasion of the terminal, which is undesirable to the user of the test socket.

### SUMMARY OF THE INVENTION

A test socket according to an embodiment of the present invention includes a socket body having a passageway, and a terminal insertable into the passageway. The passageway has a portion with an interior contour in a predetermined plane along a length axis of the passageway. The terminal includes a resilient end resiliently movable relative to the passageway. The resilient end has an exterior contour in a common plane of the passageway, with the exterior contour in shape different from that of the interior contour of the passageway, such that during the movement of the resilient end, the exterior contour of the resilient end forms in point-to-point contact with the interior contour of the passageway. As compared with the prior art, the point-to-point contact between the terminal and the passageway can effectively reduce the abrasion of the terminal.

Other features and advantages of the present invention will become more apparent to those skilled in the art upon examination of the following drawings and detailed description of preferred embodiments, in which:

### BRIEF DESCRIPTION OF THE DRAWINGS

FIG. 1 is an assembled, perspective view of a test socket according to a preferred embodiment of the present invention;

FIG. 2 is another assembled, perspective view of the test socket of FIG. 1;

FIG. 3 is an exploded, perspective view of the test socket of FIG. 2;

FIG. 4 is a sketch view showing a resilient terminal engagable with a passageway of the test socket of FIG. 2; and

FIG. 5 is a cross sectional view showing the resilient terminal received in the passageway of the test socket of FIG. 2.

### DETAILED DESCRIPTION OF PREFERRED EMBODIMENT

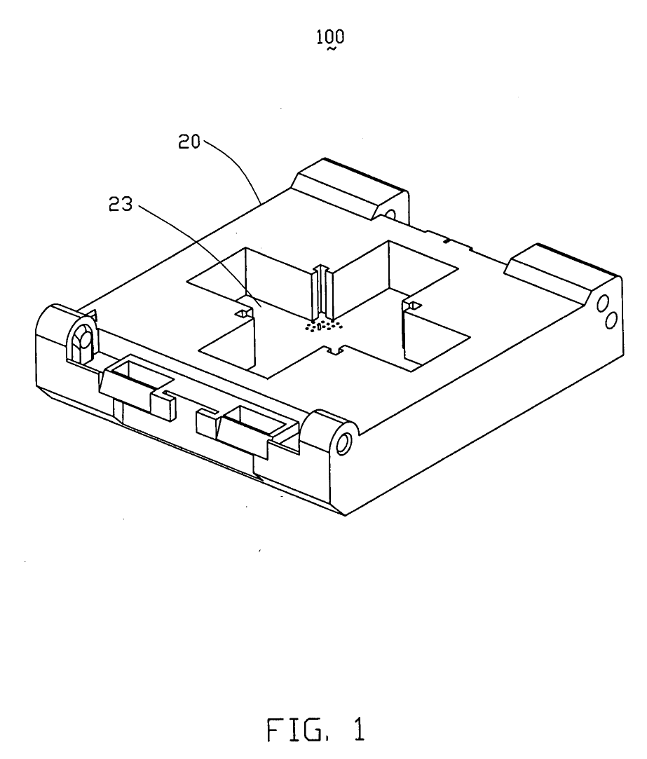

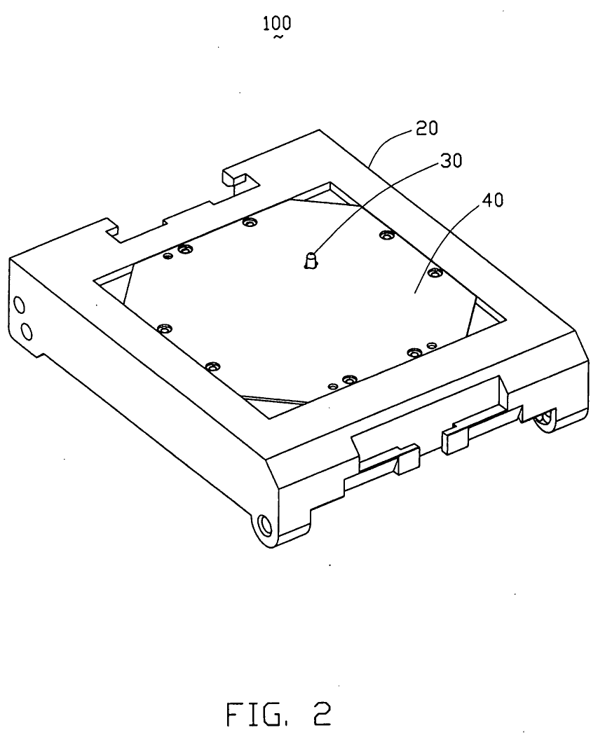

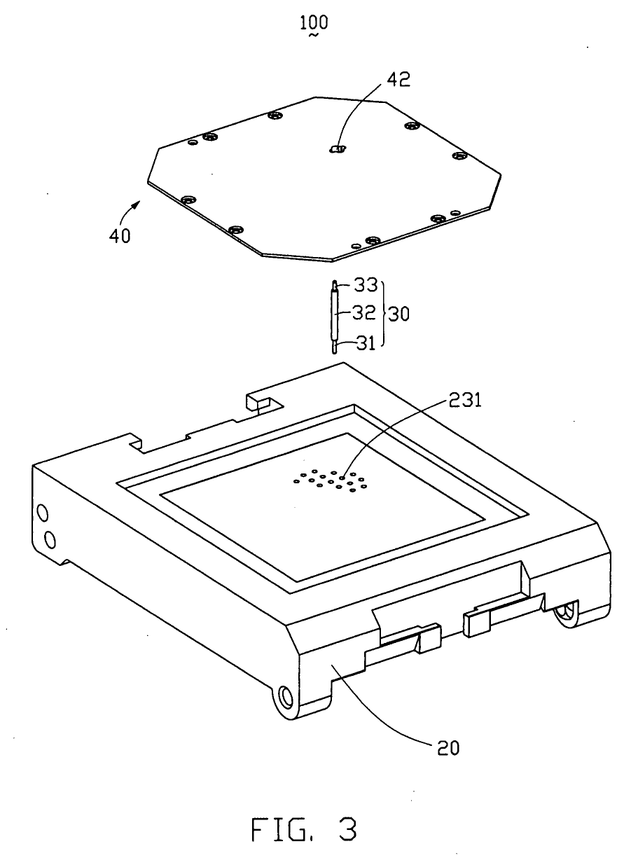

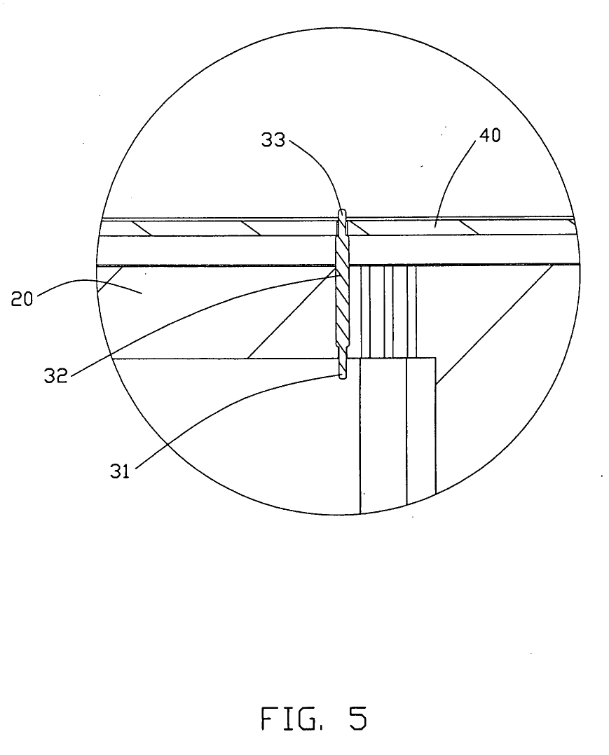

Referring to FIGS. 1 to 5, a test socket 100 according to the preferred embodiment of the present invention is shown to include a socket body 20, and a plurality of terminals 30 received within the socket body 20.

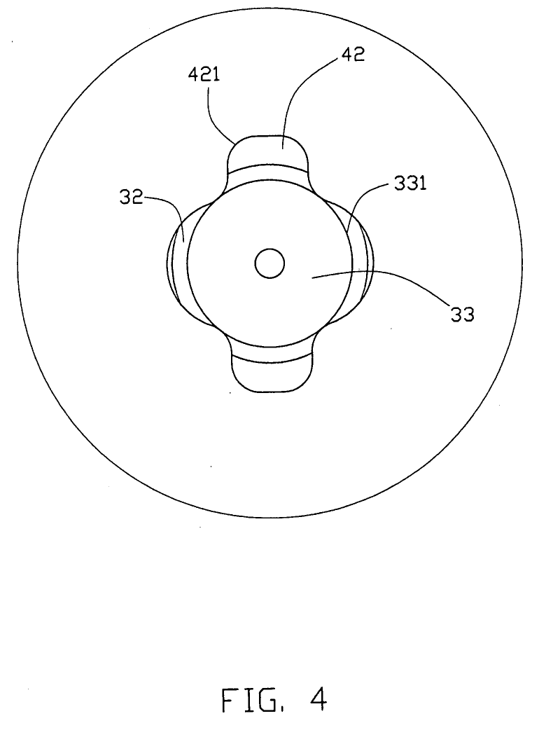

The socket body 20 defines a recessed region 23, being of a cruciform recess, for accommodating an IC package (not shown) to be tested, with a plurality of holes 231 extending through the recessed region 23 for receiving the terminals 30 in order to enable the terminals 30 to be in electrical contact with contact pads of the IC package. The socket body 20 further includes a bottom plate 40 disposed in opposite relationship with the recessed region 23 of the socket body 20, with a plurality of passageways 42 aligned with the holes 231 for the terminals 30 to further extend thereinto. The passageway 42 of the bottom plate 40 has a portion defining an interior contour 421 in any predetermined plane along a length axis of the passageway 42. In this embodiment, the interior contour 421 is of an irregular curve, in shape different from a circle, shaped to form or remain a point-to-point contact with an exterior contour 331 of the terminal 33 (in FIG. 4, to be later described).

The terminal 30 includes an upper resilient end 31, a lower resilient end 33, and a main body 32 locatable between the upper and lower resilient ends, with a radius of the main body 32 being larger than any one of the resilient ends 31 or 33. Each of the resilient ends 31 or 33 is capable of being resiliently movable relative to the main body 32 after compressed. The terminal 30 has the main body 32 received within the hole 231 of the socket body 20, with its lower resilient end 33 extending into the passageway 42 of the bottom plate 40. The lower resilient end 33 of the terminal 30 has an exterior contour in a common plane of the passageway portion 42, being of a circle shape of this embodiment, such that during the movement of the lower resilient end 33 relative to the passageway 42, the exterior contour 331 of the lower resilient end 33 remains in point-to-point contact with the interior contour 421 of the passageway 42. As compared with the prior art, the point-to-point contact between the terminal 30 and the passageway 42 can effectively reduce the abrasion of the terminal 30.

While the present invention has been described with reference to preferred embodiments, the description of the invention is illustrative and is not to be construed as limiting the invention. Various of modifications to the present invention can be made to preferred embodiments by those skilled in the art without departing from the true spirit and scope of the invention as defined by the appended claims.

What is claimed is:

1. A test socket comprising:
a socket body having a passageway, said passageway having an interior contour in a predetermined plane along a length axis of said passageway;
a terminal insertable into said passageway and including a resilient end, said resilient end of the terminal resiliently movable relative to said passageway, said resilient end having an exterior contour in a common plane of the passageway, the exterior contour in shape different from that of the interior contour of said passageway; and wherein
during the movement of said resilient end relative to said passageway, the exterior contour of said resilient end forms in point-to-point contact with the interior contour of said passageway.

2. The test socket of claim 1, wherein the exterior contour of the resilient end is of a circle shape.

3. The test socket of claim 2, wherein the interior contour of said passageway is of an irregular curved shape.

4. The test socket of claim 1, wherein the terminal includes two said resilient ends and a main body locatable between two said resilient ends, each of said resilient ends capable of being movable relative to the main body after compressed.

5. The test socket of claim 1, wherein the socket body includes a bottom plate with said passageway included, the resilient end being received within said passageway of the bottom plate.

6. A test socket comprising:
a socket body having a passageway, said passageway having an interior contour in any predetermined plane along a length axis of said passageway;
a terminal insertable into said passageway and including an end, said end of the terminal movable relative to said passageway, said end having an exterior contour in a common plane of the passageway, the exterior contour in shape different from that of the interior contour of said passageway; and wherein
during the movement of said end, the exterior contour of said end remains in point-to-point contact with the interior contour of said passageway.

7. A socket comprising:
an insulative body defining a plurality holes;
an insulative plate defining a plurality of passageways aligned with the corresponding holes, respectively, said passageways being dimensioned smaller than said holes;
a plurality of terminals each including a large main body and a small end essentially respectively disposed in the corresponding hole and passageway; wherein
the small end is axially moveable within the corresponding hole, and engagement between the hole and the small end performs point-to-point rather than face-to-face.

8. The socket as claimed in claim 7, wherein the passageway defines a wavy form on an interior face thereof.
